(19) United States
(12) Patent Application Publication
(10) Pub. No.: US 2021/0327982 A1
(43) Pub. Date: Oct. 21, 2021

(54) DISPLAY PANEL AND DISPLAY DEVICE

(71) Applicant: Wuhan China Star Optoelectronics Semiconductor Display Technology Co., Ltd, Wuhan, Hubei (CN)

(72) Inventor: Zhiwei Zhou, Wuhan, Hubei (CN)

(21) Appl. No.: 16/624,800

(22) PCT Filed: Oct. 11, 2019
(86) PCT No.: PCT/CN2019/110520

§ 371 Date: Dec. 19, 2019

(30) Foreign Application Priority Data
Aug. 30, 2019 (CN) 201910813588.5

(51) Int. Cl. H01L 27/32; H01L 51/52

(52) U.S. Cl. CPC H01L 27/3258; H01L 51/0097; H01L 51/5253; H01L 27/3276

(57) ABSTRACT

The disclosure provides a display panel and a display device. The display panel is provided with a display region and a frame region. The display region includes a plurality of pixel drive units, and each of the pixel drive units includes a plurality of thin film transistors (TFTs). Both the display region and the frame region are provided with at least one notch. The at least one notch and the pixel drive units are spaced from each other. The at least one notch sequentially extends and passes through a buffer layer, a first insulating layer, a second insulating layer, and a dielectric layer from bottom to top. An organic layer fills the at least one notch. The display device includes the display panel.

### CROSS-REFERENCE TO RELATED APPLICATIONS

This application is the National phase under 35 U.S.C. § 371 of International Application No. PCT/CN2019/110520, filed Oct. 11, 2019, which claims the benefit of and priority to Chinese Patent Application No. 201910813588.5, filed Aug. 30, 2019. The entire contents of these patent applications are hereby incorporated by reference herein.

### FIELD

The present disclosure relates to the display field and, more particularly, relates to a display panel and a display device.

### BACKGROUND

When an organic light-emitting diode (OLED) display panel is bent, microcracks that cannot be seen by the naked eye expand from a bezel region (a junction of different materials) of the OLED display panel to a display region. On the other hand, defects generated during a process of manufacturing the display region also form microcracks which expand from the display region to the bezel region when the OLED display panel is bent. Consequently, if there is no protection for the display region and the bezel region, microcracks will inevitably expand from the above two regions and threaten the entire OLED display panel so that it cannot display normally.

### SUMMARY

Based on the above considerations, it is necessary to provide a crack-stop design for each of the pixel units in the display region, which confines microcracks to a single pixel unit so that the microcracks cannot threaten other pixel units. Furthermore, the bezel region is also provided with a corresponding crack-stop design to prevent microcracks in the bezel region from expanding and directly damaging the display panel.

An object of the present disclosure is to provide a display panel and a display device. An organic layer with a grid structure is formed in the bezel region and every pixel units in the display panel, thereby effectively solving the technical problem of abnormal images caused by microcracks generated when the OLED display panel is bent and improving the display panel's dynamic bending property.

The present disclosure provides a display panel, including a flexible substrate layer, and a barrier layer, a buffer layer, an active layer, a first insulating layer, a first metal layer, a second insulating layer, a second metal layer, a dielectric layer, an organic layer, a source/drain metal layer, a planarization layer, a pixel electrode layer, and a pixel defining layer which are sequentially stacked on the flexible substrate layer from bottom to top, wherein the display panel is provided with a display region and a bezel region. The display region includes a plurality of pixel drive units, and each of the pixel drive units includes a plurality of thin film transistors (TFTs). A gate of the TFTs is disposed on the first metal layer, and a source and a drain of the TFTs are disposed on the source/drain metal layer. Both the display region and the bezel region are provided with at least one notch, the at least one notch and the pixel drive units are spaced from each other, and the at least one notch sequentially extends and passes through the buffer layer, the first insulating layer, the second insulating layer, and the dielectric layer from bottom to top. The organic layer fills the at least one notch.

Furthermore, the display panel further includes a plurality of luminescent elements, and each of the luminescent elements is electrically connected to the pixel drive unit and includes an anode disposed on the pixel electrode layer. The at least one notch and a projection of the anode on a plane on which the display panel is disposed are spaced from each other.

Furthermore, in the display region and the bezel region, the at least one notch extends along a first direction and is arranged along a second direction. In the bezel region, the at least one notch extends along the second direction and is arranged along the first direction. The first direction and the second direction are different.

Furthermore, in the bezel region, the at least one notch extending along the first direction and the at least one notch extending along the second direction are connected to each other and form in grid shape.

Furthermore, the display region further includes a plurality of scan lines and a plurality of data lines. The scan lines extend along the first direction and are arranged along the second direction, the data lines extend along the second direction and are arranged along the first direction, and the scan lines and the data lines cross each other and define the pixel drive units arranged in a plurality of arrays.

Furthermore, in the display region, the at least one notch is defined between the pixel drive units arranged along the second direction.

Furthermore, the display region is further provided with a at least one second notch extending along the second direction and arranged along the first direction.

Furthermore, the at least one second notch extends and passes through the buffer layer and the first insulating layer, wherein the at least one second notch is defined between the pixel drive units arranged along the first direction.

Furthermore, in the bezel region, the at least one second notch extending along the first direction and the at least one notch extending along the second direction are connected to each other and form in grid shape.

Furthermore, a shape of the at least one notch is a continuous strip.

The present disclosure further provides a display device including the above display panel.

Regarding the beneficial effects: The present disclosure provides the display panel and the display device. The organic layer with a grid structure is formed in the bezel region and in each of the pixel units in the display panel, thereby effectively dispersing bending stresses to reduce a crack expansion energy. Therefore, the technical problem of abnormal images caused by microcracks generated when the OLED display panel is bent is effectively improved, and the display panel's dynamic bending property is improved.

### DESCRIPTION OF DRAWINGS

FIG. 1 is a schematic plan view showing a structure of a display panel according to a first embodiment of the present disclosure.

FIG. 2 is a schematic sectional view showing the structure of the display panel according to the first embodiment of the present disclosure.

FIG. 3 is a schematic plan view showing a structure of a display panel according to a second embodiment of the present disclosure.

FIG. 4 is a schematic sectional view showing the structure of the display panel according to the second embodiment of the present disclosure.

FIG. 5 is a schematic plan view showing a structure of a display panel according to a third embodiment of the present disclosure.

FIG. 6 is a schematic sectional view showing the structure of the display panel according to the third embodiment of the present disclosure.

### DETAILED DESCRIPTION

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

### First Embodiment

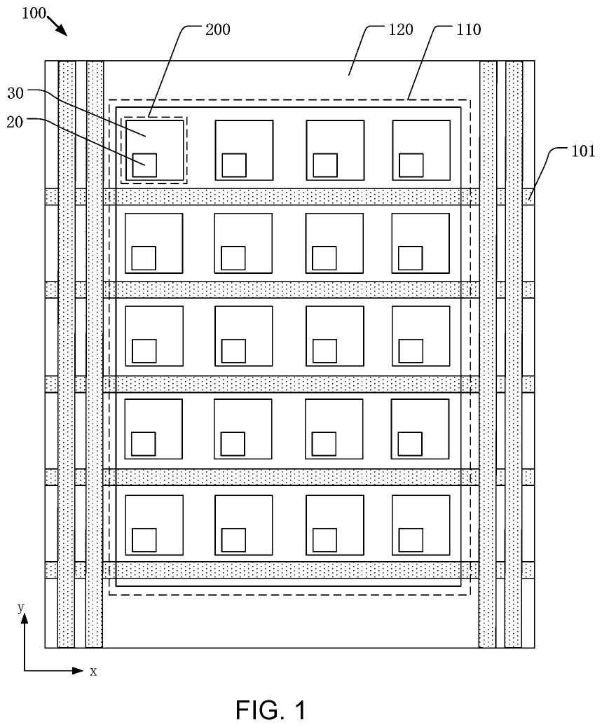

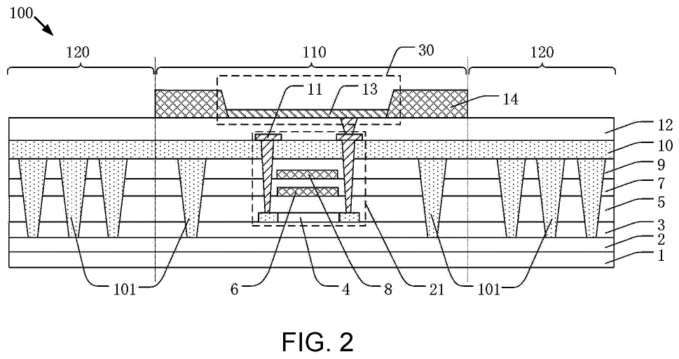

Referring to FIG. 1 and FIG. 2, the first embodiment of the present disclosure provides a display panel 100, including a flexible substrate layer 1, and a barrier layer 2, a buffer layer 3, an active layer 4, a first insulating layer 5, a first metal layer 6, a second insulating layer 7, a second metal layer 8, a dielectric layer 9, an organic layer 10, a source/drain metal layer 11, a planarization layer 12, a pixel electrode layer 13, and a pixel defining layer 14, which are sequentially stacked on the flexible substrate layer 1 from bottom to top. The display panel 100 is provided with a display region 110 and a bezel region 120. The bezel region 120 is disposed surrounding the display region 110 and is provided with a gate on array (GOA) region. The display region 110 includes a plurality of pixel drive units 20, and each of the pixel drive units 20 includes a plurality of thin film transistors (TFTs) 21. A gate of the TFTs 21 is disposed on the first metal layer 6, and a source and a drain of the TFTs are disposed on the source/drain metal layer 11. Both the display region 110 and the bezel region 120 are provided with at least one notch 101, the at least one notch 101 and the pixel drive units 20 are spaced from each other, that is, the at least one notch 101 is not overlapped with projections of the pixel drive units 20 on a plane on which the display panel 100 is disposed. The at least one notch 101 sequentially extends and passes through the buffer layer 3, the first insulating layer 5, the second insulating layer 7, and the dielectric layer 9 from bottom to top. The organic layer 10 fills the at least one notch 101.

A material of the organic layer 10 includes polyimide, colorless polyimide, or siloxane. Young's modulus of the organic layer 10 is less than or equal to 10 GPa so that the organic layer 10 can alleviate and disperse bending stresses. Therefore, a crack expansion energy is reduced, and microcracks are prevented from expanding.

The at least one notch 101 can provide a certain space to alleviate stress concentration resulting from a bending operation, thereby improving bendability of the display panel 100. Furthermore, even though microcracks occur on layers of the display panel 100 during a bending operation, the microcracks are stopped at the at least one notch 101 because the at least one notch 101 disperse stresses, preventing the microcracks from expanding to damage the layers. Therefore, not only can the TFTs 21 of the pixel drive units 20 be prevented from a short circuit, a possibility of an open circuit caused by the microcracks can also be reduced. As a result, stabilities of structures of the TFTs 21 of the pixel drive units 20 are ensured, and stability of the display panel 100 is further improved.

In the present disclosure, the display panel 100 further includes a plurality of luminescent elements 30. Each of the luminescent elements 30 is electrically connected to the pixel drive unit 20 to form a drive unit 200, and each of the luminescent elements 30 includes an anode disposed on the pixel electrode layer 13. The at least one notch 101 and a projection of the anode on a plane on which the display panel 100 is disposed are spaced from each other, that is, the at least one notch 101 and the projection of the anode on the plane on which the display panel 100 are not overlapped.

In the present disclosure, in the display region 110 and the bezel region 120, the at least one notch 101 extends along a first direction x and is arranged along a second direction y. In the bezel region 120, the at least one notch 101 extends along the second direction y and is arranged along the first direction x. The first direction x and the second direction y are different.

In the present disclosure, in the bezel region 120, the at least one notch 101 extending along the first direction x and the at least one notch 101 extending along the second direction y are connected to each other and form a grid shape which is a crack-stop structure with a grid shape. The organic layer 10 fills the above notches 101 which form the crack-stop structure with a grid shape so that pixel units 200 in the display region 110 can be covered, thereby effectively preventing microcracks in a pixel from expanding to the pixel units 200 in other regions and causing failure of the pixel units 200 in other regions. Moreover, because the at least one notch 101 in the display region 110 and the at least one notch 101 in the bezel region 120 are connected to each other and are filled with the organic layer 10, stresses generated during a bending process can be dispersed by organic materials which is evenly distributed in the grid, thereby protecting a structure of the display panel 100.

In the present embodiment, the display region 110 further includes a plurality of scan lines (not shown) and a plurality of data lines (not shown). The scan lines extend along the first direction x and are arranged along the second direction y, the data lines extend along the second direction y and are arranged along the first direction x. The scan lines and the data lines cross each other and define the pixel drive units 20 arranged in a plurality of arrays.

In the present disclosure, in the display region 110, the at least one notch 101 is defined between the pixel drive units 20 arranged along the second direction y.

In the present disclosure, a shape of the at least one notch 101 is a continuous strip. In a bending process, the at least one notch 101 and the organic layer 10 can disperse stresses occurring on any position near the at least one notch 101 and the organic layer 10; furthermore, the at least one notch 101 can block microcracks generated at any position near the at least one notch 101. Bendability of the display panel 100 is significantly improved.

### Second Embodiment

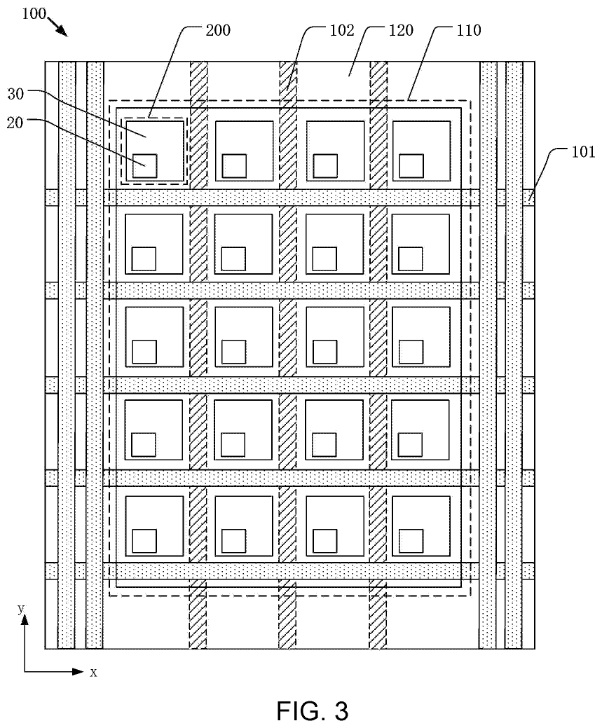

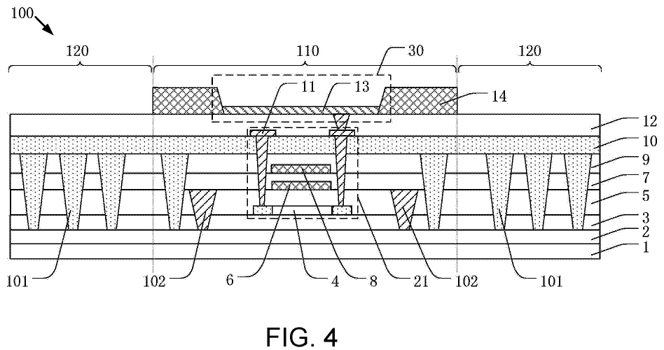

Referring to FIG. 3 and FIG. 4, the second embodiment provides a display panel 100 including all technical features of the first embodiment. Different from the first embodiment, in the second embodiment, the display region 110 further includes at least one second notch 102 extending along the second direction y and arranged along the first direction x instead of only including the at least one notch 101 extending along the first direction x and arranged along the second direction y.

In the present embodiment, the at least one second notch 102 extends and passes through the buffer layer 3 and the first insulating layer 5, wherein the at least one second notch 102 is defined between the pixel drive units 20 arranged along the first direction x.

The at least one second notch 102 can provide a certain space to alleviate stress concentration resulting from a bending operation, thereby improving bendability of the display panel 100. Furthermore, even though microcracks occur on layers of the display panel 100 during a bending operation, the microcracks are stopped at the at least one second notch 102 because the at least one second notch 102 disperse stresses, preventing the microcracks from expanding to damage the layers. Therefore, not only can the TFTs 21 of the pixel drive units 20 be prevented from a short circuit, a possibility of an open circuit caused by the microcracks can also be reduced. As a result, stabilities of structures of the TFTs 21 of the pixel drive units 20 are ensured, and stability of the display panel 100 is further improved.

An organic material filled in the at least one second notch 102 is the same as the material of the organic layer 10. The organic material includes polyimide, colorless polyimide, or siloxane. Young's modulus of the organic material is less than or equal to 10 GPa so that the organic material can alleviate and disperse bending stresses. Therefore, a crack expansion energy is reduced, and microcracks are prevented from expanding. By adding the at least one second notch 102 having the above organic material, bending stresses are further dispersed. Therefore, a crack expansion energy is further reduced, and microcracks are further prevented from expanding. Stresses generated during a bending process can be dispersed by the organic material which is evenly distributed in the grid, thereby protecting a structure of the display panel 100.

In a process of manufacturing the display panel 100, first the at least one second notch 102 is formed, and then the at least one notch 101 is formed. Furthermore, the at least one notch 101 in the display region 110 and the at least one notch 101 in the bezel region 120 are manufactured by a same mask, which can reduce manufacturing cost.

### Third Embodiment

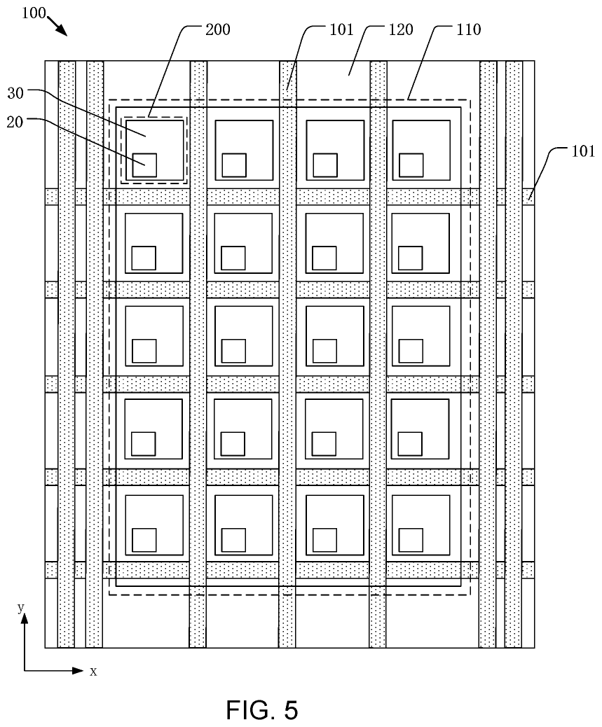

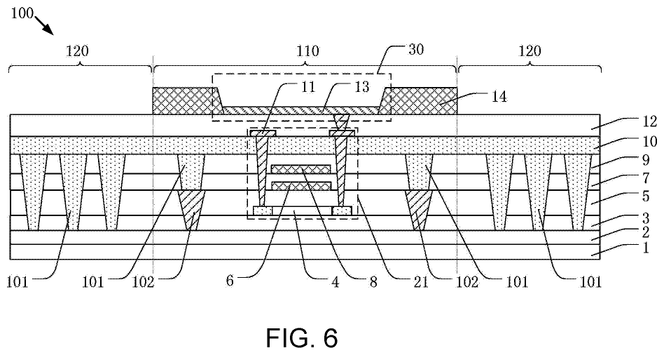

Referring to FIG. 5 and FIG. 6, the third embodiment provides a display panel 100 including most of the technical features of the second embodiment. Different from the second embodiment, in the third embodiment, the at least one second notch 102 in the display region 110 extends along the first direction x and is connected to the at least one notch 101 arranged along the second direction y to form a grid shape instead of being separated from the at least one notch 101.

The at least one second notch 102 and the at least one notch 101 are connected to each other and form a grid shape; specifically, the at least one notch 101 in the bezel region 120, the at least one second notch 102, and the at least one notch 101 in the display region 110 are connected to each other and form a crack-stop structure with a grid shape. That is, the organic layer 10 filled in the at least one notch 101 is connected to the organic material filled in the at least one second notch 102. The pixel units 200 in the display region 110 are covered by the organic material with a grid shape, thereby effectively preventing microcracks in a pixel from expanding to the pixel units 200 in other regions and causing failure of the pixel units 200 in other regions. Moreover, because the at least one notch 101 in the display region 110, the at least one second notch 102, and the at least one notch 101 in the bezel region 120 are connected to each other and are filled with the organic material, stresses generated during a bending process can be dispersed by the organic material which is evenly distributed in the grid, thereby protecting a structure of the display panel 100.

The present disclosure further provides a display device, including the above display panel 100.

Regarding the beneficial effects: The present disclosure provides the display panel and the display device. The organic layer with a grid structure is formed in the bezel region and in each of the pixel units in the display panel, thereby effectively dispersing bending stresses to reduce a crack expansion energy. Therefore, the technical problem of abnormal images caused by microcracks when the OLED display panel is bent is effectively improved, and the display panel's dynamic bending property is improved.

The above are merely preferred embodiments of the present invention. It is understood that many changes and modifications to the described embodiment can be carried out without departing from the scope and the spirit of the disclosure that is intended to be limited only by the appended claims.

1. A display panel, comprising a flexible substrate layer, and a barrier layer, a buffer layer, an active layer, a first insulating layer, a first metal layer, a second insulating layer, a second metal layer, a dielectric layer, an organic layer, a source/drain metal layer, a planarization layer, a pixel electrode layer, and a pixel defining layer, which are sequentially stacked on the flexible substrate layer from bottom to top, wherein the display panel is provided with a display region and a bezel region;
wherein the display region comprises a plurality of pixel drive units, each of the pixel drive units comprises a plurality of thin film transistors (TFTs), a gate of the TFTs is disposed on the first metal layer, and a source and a drain of the TFTs are disposed on the source/drain metal layer; and
wherein both the display region and the bezel region are provided with at least one first notch, the at least one first notch and the pixel drive units are spaced from each other, the at least one first notch sequentially extends and passes through the buffer layer, the first insulating layer, the second insulating layer, and the dielectric layer from bottom to top, and the organic layer fills the at least one first notch.

2. The display panel of claim 1, wherein the display panel comprises a plurality of luminescent elements, each of the luminescent elements is electrically connected to the pixel drive units and comprises an anode disposed on the pixel electrode layer, and the at least one first notch and a projection of the anode on a plane on which the display panel is disposed are spaced from each other.

3. The display panel of claim 1, wherein in the display region and the bezel region, the at least one first notch extends along a first direction and is arranged along a second direction;
wherein in the bezel region, the at least one first notch extends along the second direction and is arranged along the first direction; and
wherein the first direction and the second direction are different.

4. The display panel of claim 3, wherein in the bezel region, the at least one first notch extending along the first direction and the at least one first notch extending along the second direction are connected to each other and form a grid shape.

5. The display panel of claim 3, wherein the display region further comprises a plurality of scan lines and a plurality of data lines, the scan lines extend along the first direction and are arranged along the second direction, the data lines extend along the second direction and are arranged along the first direction, and the scan lines and the data lines cross each other and define the pixel drive units arranged in a plurality of arrays.

6. The display panel of claim 3, wherein in the display region, the at least one first notch is defined between the pixel drive units arranged along the second direction.

7. The display panel of claim 3, wherein the display region is further provided with at least one second notch extending along the second direction and arranged along the first direction.

8. The display panel of claim 7, wherein the at least one second notch extends and passes through the buffer layer and the first insulating layer, and the at least one second notch is defined between the pixel drive units arranged along the first direction.

9. The display panel of claim 7, wherein the at least one second notch and the at least one first notch extending along the first direction and arranged along the second direction are connected to each other and form a grid shape.

10. The display panel of claim 1, wherein a shape of the at least one first notch is a continuous strip.

11. A display device, comprising the display panel of claim 1.
